(19) United States
(12) Patent Application Publication
(10) Pub. No.: US 2026/0013195 A1
(43) Pub. Date: Jan. 8, 2026

(54) MANUFACTURING METHOD OF SEMICONDUCTOR DEVICE AND SEMICONDUCTOR DEVICE

(71) Applicant: ROHM CO., LTD., Kyoto (JP)

(72) Inventor: Masahiko TSUTSUI, Kyoto (JP)

(73) Assignee: ROHM CO., LTD., Kyoto (JP)

(21) Appl. No.: 19/256,902

(22) Filed: Jul. 1, 2025

(30) Foreign Application Priority Data
Jul. 3, 2024 (JP) 2024-107496

(51) Int. Cl. H10D 64/01; H01L 21/768; H01L 23/48; H10D 64/27

(52) U.S. Cl. CPC H10D 64/027; H01L 21/76898; H01L 23/481; H10D 64/513

(57) ABSTRACT

A manufacturing method of a semiconductor device includes forming a semiconductor layer of a first conductivity type that is located on a substrate, simultaneously forming a first trench having the semiconductor layer as a bottom surface and a second trench that runs through the semiconductor layer, simultaneously forming an insulator that fills up the first trench and an insulating layer that covers the second trench, removing a part of the insulator such that the bottom surface of the first trench is not exposed, removing a part of the insulating layer such that the semiconductor substrate is exposed in the second trench, embedding in the first trench a first conductor that is separated from the semiconductor layer, and embedding in the second trench a second conductor that is in contact with the semiconductor substrate. A width of the second trench is greater than a width of the first trench.

### CROSS REFERENCE TO RELATED APPLICATION

This application is based upon and claims the benefit of priority of the prior Japanese Patent Application No. 2024-107496, filed on Jul. 3, 2024, the entire contents of which are incorporated herein by reference.

### TECHNICAL FIELD

The present disclosure relates to a manufacturing method of semiconductor devices and a semiconductor device.

### BACKGROUND ART

Japanese Patent Application Laid-open Publication No. 2009-295778 discloses a manufacturing method of a vertical trench MOSFET.

### BRIEF DESCRIPTION OF THE DRAWINGS

FIG. 1 is a schematic plan view of a semiconductor device of an embodiment.

FIG. 2 is a schematic cross-sectional view along the line II-II of FIG. 1.

FIG. 3 is a schematic cross-sectional view for explaining one example of a semiconductor device of an embodiment.

FIG. 4 is a schematic cross-sectional view for explaining one example of a manufacturing method of a semiconductor device of an embodiment.

FIG. 5 is a schematic cross-sectional view for explaining one example of a manufacturing method of a semiconductor device of an embodiment.

FIG. 6 is a schematic cross-sectional view for explaining one example of a manufacturing method of a semiconductor device of an embodiment.

FIG. 7 is a schematic cross-sectional view for explaining one example of a manufacturing method of a semiconductor device of an embodiment.

FIG. 8 is a schematic cross-sectional view for explaining one example of a manufacturing method of a semiconductor device of an embodiment.

FIG. 9A is a schematic cross-sectional view for explaining one example of a manufacturing method of each trench structure.

FIG. 9B is a schematic cross-sectional view for explaining one example of a manufacturing method of each trench structure.

FIG. 9C is a schematic cross-sectional view for explaining one example of a manufacturing method of each trench structure.

FIG. 9D is a schematic cross-sectional view for explaining one example of a manufacturing method of each trench structure.

FIG. 9E is a schematic cross-sectional view for explaining one example of a manufacturing method of each trench structure.

FIG. 10 is a cross-sectional perspective view showing a main part of a semiconductor device according to a reference example.

### DETAILED DESCRIPTION OF EMBODIMENTS

Below, an embodiment of the present disclosure will be explained in detail with reference to the appended drawings. In the description below, the same components or components having the same function are given the same reference character and the descriptions thereof will not be repeated. The term “same” or any other terms similar to that in this specification are not limited to “exactly the same”. The figures are for explaining the embodiment conceptually, and therefore, the dimensions and ratios of the respective components may differ from the actual dimensions and ratios.

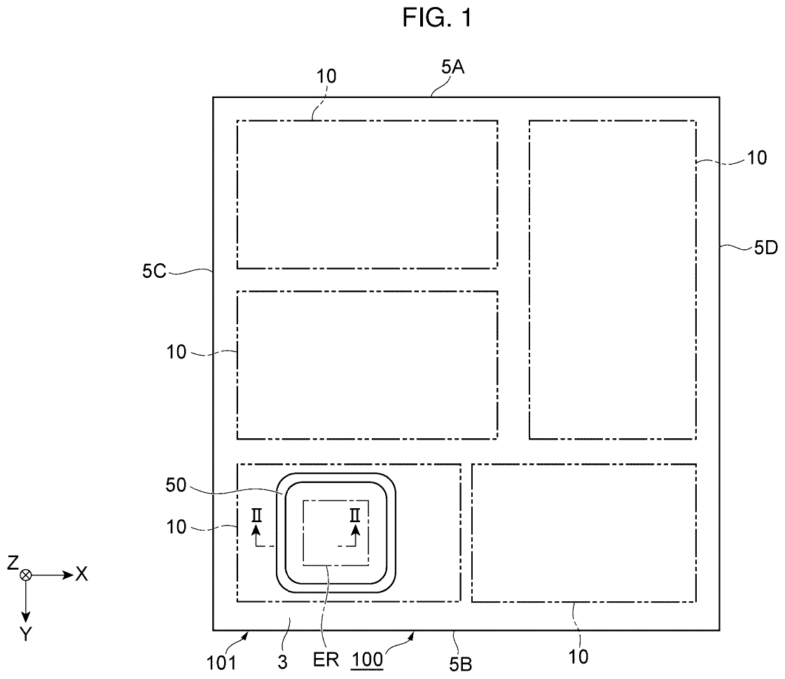

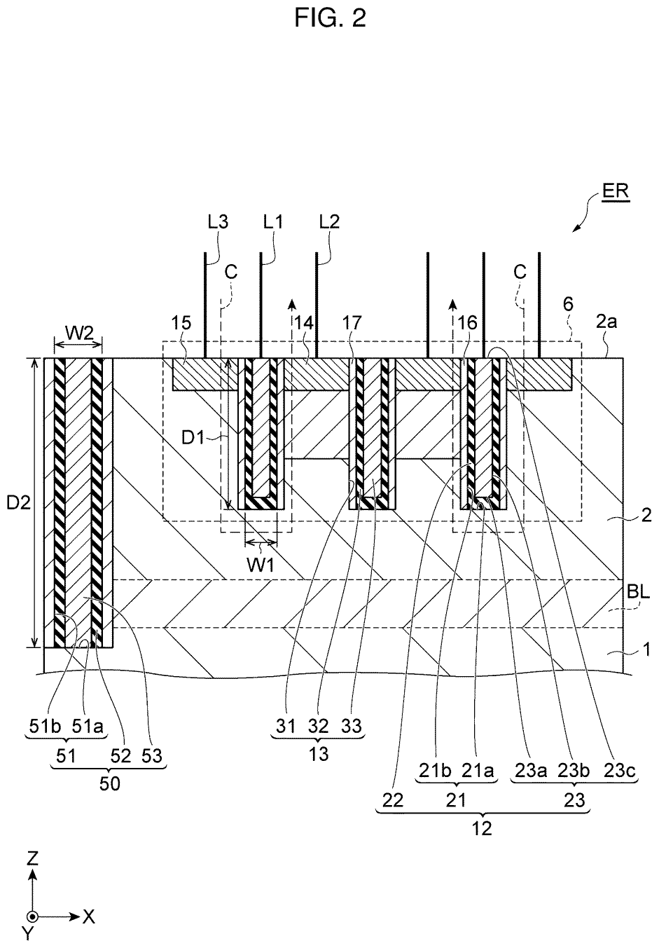

FIG. 1 is a schematic plan view of a semiconductor device of an embodiment of the present disclosure. FIG. 2 is a schematic cross-sectional view along the line II-II of FIG. 1.

As illustrated in FIG. 1, a semiconductor device 100 includes a chip-shaped integrated circuit (IC), for example. The semiconductor device 100 may be referred to as an SSI (Small Scale IC), MSI (Medium Scale IC), LSI (Large Scale IC), VLSI (Very Large Scale IC), ULSI (Ultra Large Scale IC) and the like, based on the number of circuit elements integrated therein. The semiconductor device 100 is used for LSI equipped with a reference voltage circuit (VREF circuit), for example. In this embodiment, the semiconductor device 100 includes a cuboid chip 101 (semiconductor chip).

The chip 101 has a first main surface 3, which is the top surface, and a second main surface 4, which is the bottom surface. The chip 101 has a first side surface 5A, a second side surface 5B, a third side surface 5C, and a fourth side surface 5D that connect the first main surface 3 and the second main surface 4. Below, the thickness direction of the chip 101 (thickness direction of the semiconductor layer 2 described below) corresponds to the z-axis direction, the direction perpendicular to the thickness direction corresponds to the x-axis direction, and the direction parapedicular to both the z-axis direction and x-axis direction corresponds to the y-axis direction. Also, a view from the z-axis direction is a plan view, and the direction extending along the x-axis direction and y-axis direction is the planar direction. In the z-axis direction, the direction going toward the first main surface 3 is the upward direction, and the direction going toward the second main surface 4 is the downward direction. Below, a view from the z-axis direction may simply be referred to as a plan view.

The first main surface 3 and the second main surface 4 are each a surface that extends perpendicularly to the z axis. The plan view shape of the first main surface 3 and the plan view shape of the second main surface 4 are respectively a quadrilateral, but not limited thereto. The first side surface 5A and the second side surface 5B are each extending along the x-axis direction in a plan view. The third side surface 5C and the fourth side surface 5D are each extending along the y-axis direction in a plan view.

The semiconductor device 100 includes a plurality of device regions 10. There is a gap between each device region 10 and each side surface (from the first side surface 5A to the fourth side surface 5D) of the chip 101. The device regions 10 can take any number, any arrangement and any shape, and are not limited to specific number, arrangement or shape. In each device region 10, various types of devices are formed. As illustrated in FIG. 2, at least one device region 10 includes an element region ER surrounded by a trench structure 50 in a plan view. The element region ER may include at least one of a semiconductor switching device, a semiconductor rectifier device, and a receptor device. The semiconductor switching device may include at least one of a junction effect transistor (JFET), a metal insulator semiconductor field effect transistor (MISFET), a bipolar junction transistor (BJT), and an insulated gate bipolar junction transistor (IGBT).

For the MISFET, a MOSFET (metal oxide semiconductor field effect transistor) may be used. The MOSFET may be an enhancement type or a depression type. The MOSFET may have a planar structure, or vertical structure. The element region ER may be a power transistor. The drain-to-source voltages of MISFETs include HV (high voltage: between 100V and 1000V, for example), MV (middle voltage: between 30V and 100V, for example) and LV (low voltage: between 1V and 30V, for example). In addition, as the element region ER formed in the device region 10, an optical device such as a light emitting element or a light receiving element can be used.

In this embodiment, the semiconductor material that constitutes the chip 101 is silicon (Si), but is not limited thereto. A compound semiconductor may alternatively be used for the semiconductor material that constitutes the chip 101. The compound semiconductor may be a III-V compound semiconductor, IV-IV compound semiconductor, and an alloy semiconductor using these semiconductors. The III-V compound semiconductor is a Ga semiconductors such as GaAs or GaN, for example. The IV-IV compound semiconductor is an Si semiconductors such as SiC and SiGe, for example.

As illustrated in FIGS. 1 and 2, a device region 10 constituting a semiconductor device includes a semiconductor substrate 1 and a semiconductor layer 2 located on the semiconductor substrate 1. The semiconductor substrate 1 functions as a base substrate in forming the semiconductor layer 2, and may be a single crystal Si substrate, single crystal SiC substrate, or the like, for example. The semiconductor layer 2 is an epitaxial layer formed on the semiconductor substrate 1 as a base. The main surface 2a of the semiconductor layer 2 corresponds to the first main surface 3 of the chip 101, but is not limited thereto. In the device region 10, a buried region BL, an element region ER located on the buried region BL, and a trench structure 50 surrounding the element region ER in a plan view are defined. The buried region BL is formed at least in the semiconductor layer 2. In addition to the semiconductor layer 2, the buried region BL may be formed in the semiconductor substrate 1.

For the respective semiconductor regions constituting the semiconductor device, n type is considered the first conductive type, and p type is considered the second conductive type that differs from the first conductive type in this embodiment, but those conductive types may be switched. That is, the first conductive type may be p type and the second conductive type may be n type. Examples of p type impurity (trivalent atom) includes boron (B). Examples of n type impurity (pentavalent atom) includes phosphorus (P) and arsenic (As). The semiconductor substrate 1 of this embodiment is made of Si. In this embodiment, the semiconductor substrate 1 exhibits the second conductive type, the semiconductor layer 2 exhibits the first conductive type, and the buried region BL exhibits the first conductive type.

The impurity concentration of the semiconductor substrate 1 may be 1.0×10¹⁵ cm⁻³ or greater and less than or equal to 1.0×10¹⁸ cm⁻³. The thickness of the semiconductor substrate 1 may be 50 μm or greater and less than or equal to 500 μm. The impurity concentration of the buried region BL may be 1.0×10¹⁷ cm⁻³ or greater and less than or equal to 1.0×10²⁰ cm⁻³. The impurity concentration of the semiconductor layer 2 may be 1.0×10¹⁵ cm⁻³ or greater and less than or equal to 1.0×10¹⁸ cm⁻³. The thickness of the semiconductor layer 2 may be 5 μm or greater and less than or equal to 50 μm.

There is no special limitation on the structure of the element region. Below, the structure of the element region ER of this embodiment will be explained. In this embodiment, the element region ER includes a vertical transistor. The element region ER has an impurity region 11 located in the semiconductor layer 2, trench structures 12 and 13 formed in the semiconductor layer 2 and adjacent to the impurity region 11, a first contact region 14 located on the impurity region 11 in the semiconductor layer 2, and a second contact region 15 located in the semiconductor layer 2. In addition, the element region ER may include wiring L1 connected to the trench structure 12, wiring L2 connected to the first contact region 14, and wiring L3 connected to a second contact region 15. In the element region ER, a part of the semiconductor layer 2, the trench structure 12, the first contact region 14, and the second contact region 15 form a vertical MOSFET 6. In this embodiment, the MOSFET 6 is the depression type. Thus, the MOSFET 6 is a normally-on transistor.

The impurity region 11 is a well region of the second conductivity type, disposed in the center of the element region ER. With the impurity region 11, when a prescribed potential is applied to the gate (described later) of the MOSFET 6, the MOSFET 6 turns off. The impurity region 11 is separated from the buried region BL. In other words, the impurity region 11 is located above the buried region BL in the z-axis direction. The impurity region 11 is formed by introducing (adding, doping) a second conductivity type impurity to a part of the semiconductor layer 2, for example. The impurity concentration of the impurity region 11 is 1.0×10¹⁵ cm⁻³ or greater and less than or equal to 1.0×10¹⁹ cm⁻³, for example. The dimension of the impurity region 11 along the z-axis direction is 0.5 μm or greater and less than or equal to 1.5 μm, for example.

The trench structure 12 is a part (shallow trench) adjacent to an outer edge 11a of the impurity region 11 in a plan view, and is separated from the buried region BL. In other words, the trench structure 12 is located above the buried region BL in the z-axis direction. The trench structure 12 has a trench 21 having the semiconductor layer 2 as the bottom surface thereof (first trench), an insulator 22 that covers the surface of the trench 21, and a conductor 23 located in the trench 21 and separated from the semiconductor layer 2 (first conductor).

The trench 21 is a recess (trench) formed in the semiconductor layer 2, extending from the first main surface 3 toward the second main surface 4 in the z-axis direction. The semiconductor layer 2 serves as the bottom surface of the trench 21. The trench 21 has a ring shape that surrounds the impurity region 11 and the first contact region 14 in a plan view, for example, but is not limited thereto. The trench 21 may have a shape that partially surrounds a part of the impurity region 11 in a plan view, for example. The bottom surface 21a of the trench 21 (part of the surface of the trench 21) is located closer to the semiconductor substrate 1 than the impurity region 11 in the z-axis direction Z, but is separated from the buried region BL. In other words, the bottom surface 21a is located below the impurity region 11. From the perspective of reducing the size of the MOSFET 6 or the like, the shorter side of the trench 21 in a plan view (width W1) is set to 0.5 μm or greater and less than or equal to 2.4 μm, for example. The dimension of the trench 21 along the z-axis direction (depth D1) is 1.5 μm or greater and less than or equal to 9.5 μm, for example. Thus, the ratio of the width W1 of the trench 21 to the depth D1 of the trench 21 is 0.05 or greater and less than or equal to 1.6, for example. The width W1 remains unchanged, but is not limited thereto. For example, the width W1 may become smaller as it goes down in the z-axis direction. In other words, the width at the bottom of the trench 21 may be the smallest. Therefore, in this embodiment, the width W1 corresponds to the maximum value of the shorter side of the trench 21 in a plan view.

The side surface 21b of the trench 21 (another part of the surface of the trench 21) is located in the semiconductor layer 2, and is defined by the second impurity region 16 of the first conductivity type. The second impurity region 16 is a region formed by the side surface 21b in the semiconductor layer 2, and can function as the depression portion (channel) of the MOSFET 6. In this embodiment, the second impurity region 16 is a region formed during the forming process of the trench structure 12 as described below, and thus, is considered part of the trench structure 12 and the side surface 21b of the trench 21. Therefore, the trench structure 12 (the second impurity region 16 in actuality) is adjacent to the impurity region 11. From the perspective of the channel performance of the MOSFET 6, the impurity concentration of the second impurity region 16 is 1.0×10¹⁴ cm⁻³ or greater and less than or equal to 1.0×10¹⁷ cm⁻³, for example, and the thickness of the second impurity region 16 along the direction orthogonal to the z-axis direction is 30 nm or greater and less than or equal to 300 nm, for example.

The insulator 22 is an insulating component that functions as a gate insulating film of the MOSFET 6, and covers the bottom surface 21a and side surface 21b of the trench 21. The insulator 22 is formed of an oxide insulating film such as a silicon oxide film or an aluminum oxide film, a nitride insulating film such as a silicon nitride film, or an oxynitride insulating film such as a silicon oxynitride film, for example. From the perspectives of the channel performance of the MOSFET 6 and prevention of a short circuit inside the MOSFET 6, the thickness of the insulator 22 is set to 3 nm or greater and less than or equal to 200 nm, for example. In the insulator 22, the thickness of the part that is in contact with the bottom surface 21a only, and the thickness of the part that is in contact with the side surface 21b only may differ from each other, or may be the same as each other.

The conductor 23 is a component that functions as the gate of the MOSFET 6, and located inside the insulator 22 in the trench 21. The amount of electric current that flows through a part of the second impurity region 16 between the conductor 23 and the impurity region 11 (channel) can be adjusted in accordance with the voltage applied to the conductor 23. The bottom surface 23a and side surface 23b are covered by the insulator 22. The top surface 23c of the conductor 23 is exposed from the insulator 22, and connected to the wiring L1. For the gate performance of the conductor 23, the bottom surface 23a of the conductor 23 is located closer to the semiconductor substrate 1 than the impurity region 11 in the z-axis direction. In other words, the bottom surface 23a of the conductor 23 is located below the impurity region 11. The conductor 23 is a metal such as aluminum (Al), copper (Cu), molybdenum (Mo), or tungsten (W), or polysilicon having the first or second conductivity type, for example.

The trench structure 13 is a part (shallow trench) that runs through the center of the impurity region 11 in a plan view, and is separated from the buried region BL. In other words, the trench structure 13 is located above the buried region BL in the z-axis direction. The trench structure 13 may be electrically connected to the trench structure 12. In this case, the trench structure 13 can also function as the gate of the MOSFET 6. Thus, with the trench structure 13, it is possible to expand the current path of the MOSFET 6 and the like. The trench structure 13 does not have to be electrically connected to the trench structure 12. In this case, the trench structure 13 can be applied with a potential differing from that for the trench structure 12. Thus, in the device region 10, a MOSFET using the trench structure 13 as the gate thereof may be provided in addition to the MOSFET 6 that uses the trench structure 12 as the gate thereof. The trench structure 13 has a trench 31 with the semiconductor layer 2 being the bottom surface thereof, an insulator 32 that covers the surface of the trench 31, and a conductor 33 located in the trench 31 and separated from the semiconductor layer 2.

As described below, the trench structure 13 is formed at the same time as the trench structure 12. Thus, the trench 31, the insulator 32, and the conductor 33 have the similar characteristics and configurations to those of the trench 21, the insulator 22, and the conductor 23 of the trench structure 12. Below, differences between the trench 31 and the trench 21, and differences between the conductor 33 and the conductor 23 will be explained. The trench 31 is surrounded by the impurity region 11 in a plan view, for example, but not limited thereto. The short side of the trench 31 is approximately the same as the width W1 of the trench 21, and the depth of the trench 31 is approximately the same as the depth D1 of the trench 21. The side surface 31b of the trench 31 is defined by a third impurity region 17, which is considered the side surface of the trench 31, in a manner similar to the trench 21, but is not limited thereto. The impurity concentration and thickness of the third impurity region 17 are approximately the same as the impurity concentration and thickness of the second impurity region 16. The conductor 33 is in a floating state, but not limited thereto. When the conductor 23 is applied with a prescribed voltage, the conductor 33 may be applied with a voltage differing from the prescribed voltage, or may be applied with the prescribed voltage.

The first contact region 16 is a region that functions as one of the source and drain of the MOSFET 6, and in contact with the side surface 21b of the trench 21 and the side surface 31b of the trench 31. The first contact region 14 is of the first conductivity type. The first contact region 14 is located inside the trench structure 12 in a plan view, and surrounds at least part of the trench structure 13. Thus, the first contact region 14 is in contact with the inner side surface of the side surface 21b of the trench 21. In this embodiment, the first contact region 14 and a part of the second impurity region 16 located above the impurity region 11 in the z-axis direction have configurations differing from each other, but are not limited thereto. Part of the inner side surface may be constituted of the first contact region 14. The impurity concentration of the first contact region 14 is 1.0×10¹⁸ cm⁻³ or greater and less than or equal to 1.0×10²¹ cm⁻³, for example.

The second contact region 15 is a region that functions as the other of the source and drain of the MOSFET 6, and in contact with the side surface 21b of the trench 21. The second contact region 15 is of the first conductivity type. The second contact region 15 is located outside the trench structure 12 in a plan view. Thus, the second contact region 15 is in contact with the outer side surface of the side surface 21b of the trench 21. The second contact region 15 has a ring shape that surrounds the trench structure 12 including the trench 21 in a plan view, for example, but is not limited thereto. In this embodiment, the second contact region 15 and a part of the second impurity region 16 located above the impurity region 11 in the z-axis direction have configurations differing from each other, but are not limited thereto. Part of the outer side surface may be constituted of the second contact region 15. The impurity concentration of the second contact region 15 is 1.0×10¹⁸ cm⁻³ or greater and less than or equal to 1.0×10²¹ cm⁻³, for example.

The first contact region 14 is applied with one of the source voltage and drain voltage via the wiring L2. The second contact region 15 is applied with the other of the source voltage and drain voltage via the wiring L3. In this case, electric current C flows from the second contact region 15 to the first contact region 14 via the semiconductor layer 2, the second impurity region 16, and the like, for example. When the gate voltage is applied to the conductor 23 of the trench structure 12 via the wiring L1, the current C is shut off or restricted in a portion of the second impurity region 16 between the trench structure 12 and the impurity region 11.

Next, the trench structure 50 will be explained in detail. The trench structure 50 is an element separating structure that electrically separates the element region ER from other device regions 10, and is deep trench isolation (DTI) formed in the semiconductor substrate 1. The trench structure 50 has a ring shape surrounding the element region ER in a plan view. Thus, the element region ER is surrounded by the trench structure 50 and the buried region BL. The trench structure 50 is separated from the element region ER, but in contact with the buried region BL. The trench structure 50 has a trench 51 (second trench), an insulating layer 52 that partially covers the surface of the trench 51, and a conductor (second conductor) 53 located inside the trench 51 and separated from the semiconductor layer 2.

The trench 51 is a recess (trench) that runs through the semiconductor layer 2, extending from the first main surface 3 toward the second main surface 4 in the z-axis direction. The semiconductor substrate 1 serves as the bottom surface of the trench 51. The trench 51 has a ring shape surrounding each component of the MOSFET 6 (such as the impurity region 11, the trench 21, the first contact region 14, the second contact region 14) in a plan view, for example. The bottom surface 51a of the trench 51 (part of the surface of the trench 51) is located below the buried region BL in the z-axis direction, separated from the buried region BL. The shorter side of the trench 51 in a plan view (width W2) is greater than the width W1 of the trench 21, and is set to 2.5 μm or greater and less than or equal to 4.5 μm, for example. Thus, the width W2 of the trench 51 is 104% or greater and less than or equal to 900%, for example. The dimension of the trench 51 along the z-axis direction (depth D2) is greater than the dimension of the trench 21 (depth D1), and is set to 20 μm or greater and less than or equal to 40 μm, for example. The width W2 remains unchanged, but is not limited thereto. For example, the width W2 may become smaller as it goes down in the z-axis direction. Therefore, in this embodiment, the width W2 corresponds to the maximum value of the shorter side of the trench 51 in a plan view. The ratio of the width W2 of the trench 51 to the depth D2 of the trench 51 is 0.06 or greater and less than or equal to 0.225, for example. In addition, the ratio of the width W1 of the trench 21 to the depth D1 of the trench 21 is 22% or greater and less than or equal to 2667%, 3.7% or greater and less than or equal to 450%, or the like of the ratio of the width W2 of the trench 51 to the depth D2 of the trench 51, for example. As described below, the trench 51 is formed at the same time as the trenches 21 and 31.

The side surface 51b of the trench 51 (another part of the surface of the trench 51) is defined by a fourth impurity region 18 of the first conductivity type located inside the semiconductor substrate 1 and semiconductor layer 2. The fourth impurity region 18 is a region formed along the side surface 51b in the semiconductor substrate 1 and semiconductor layer 2. In this embodiment, the fourth impurity region 18 is a region formed during the forming process of the trench structure 50 as described below, and thus, is considered part of the trench structure 50 and the side surface 51b of the trench 51. As described below, the fourth impurity region 18 is formed at the same time as the second impurity region 16. Thus, the impurity concentration and thickness of the fourth impurity region 18 are approximately the same as the impurity concentration and thickness of the second impurity region 16.

The insulating layer 52 is a component that prevents the semiconductor layer 2 and the conductor 53 from making contact with each other, and at least covers the side surface 51b of the trench 51. In this embodiment, the insulating layer 52 covers a part of the bottom surface 51a of the trench 51 in addition to the side surface 51b of the trench 51. In other words, another part of the bottom surface 51a of the trench 51 is exposed from the insulating layer 52. The insulating layer 52 is formed of an oxide insulating film, nitride insulating film, oxynitride insulating film, or the like as described above, for example. From the perspectives of preventing contact with the semiconductor layer 2 and the like, the thickness of the insulating layer 52 is 3 nm or greater and less than or equal to 200 nm, for example. As described below, the insulating layer 52 is formed at the same time as the insulators 22 and 32.

The conductor 53 is a component located on the inner side of the trench 51 than the insulating layer 52, and is in contact with the semiconductor substrate 1. The conductor 53 is a frame-shaped conductor that is surrounded by the insulating layer 52 in a plan view, extending from the first main surface 3 toward the second main surface 4 in the z-axis direction. The conductor 53 is embedded in the trench 51, and in contact with a part of the semiconductor substrate 1 below the buried region BL. This makes the potential of the conductor 53 aligned with the potential of the semiconductor substrate 1. The conductor 53 is a metal such as aluminum (Al), copper (Cu), molybdenum (Mo), or tungsten (W), or polysilicon having the first or second conductivity type, for example. As described below, the conductor 53 is formed at the same time as the conductors 23 and 33.

Although not shown in the figure, from the perspective of reducing a leak current and the like, STI (shallow trench isolation) or the like may be formed between the second contact region 15 and the trench structure 50. The STI is a part where an insulator is embedded in a recess formed in a part of the semiconductor layer 2 between the second contact region 15 and the trench structure 50, for example. The STI has a ring shape that surrounds the second contact region 15 in a plan view, for example, but is not limited thereto. The bottom surface of the STI is located below the bottom surface of the second contact region 15, but not limited thereto.

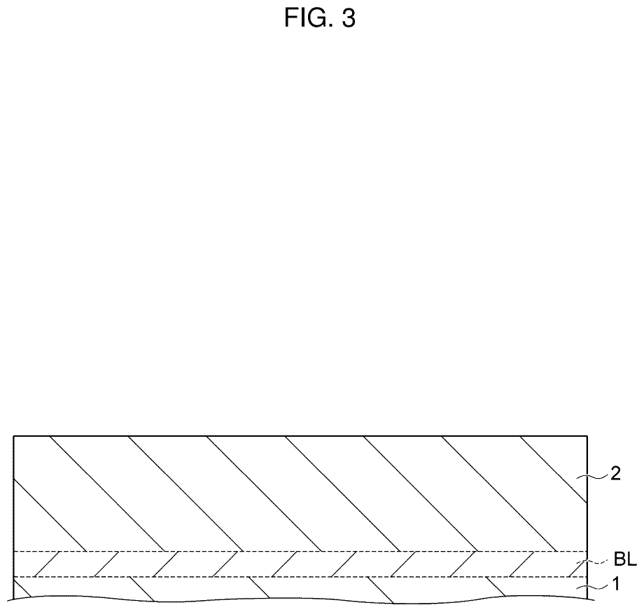

Next, with reference to FIGS. 3 to 8, an example of the manufacturing method of the semiconductor device 100 according to this embodiment will be explained. FIGS. 3 to 8 are each a schematic cross-sectional view for explaining one example of the manufacturing method of the semiconductor device 100 according to this embodiment.

First, as illustrated in FIG. 3, the semiconductor layer 2 of the first conductivity type is formed on the semiconductor substrate 1 (Step 1). In Step 1, the semiconductor layer 2 is formed by growing a semiconductor on the semiconductor substrate 1 by epitaxy. In Step 1, the semiconductor layer 2 is formed at the same time as forming the buried region BL by adjusting the amount of added impurity or the like. The impurity injection to the semiconductor substrate 1 and/or the semiconductor layer 2 is performed by a known method such as ion implantation, for example.

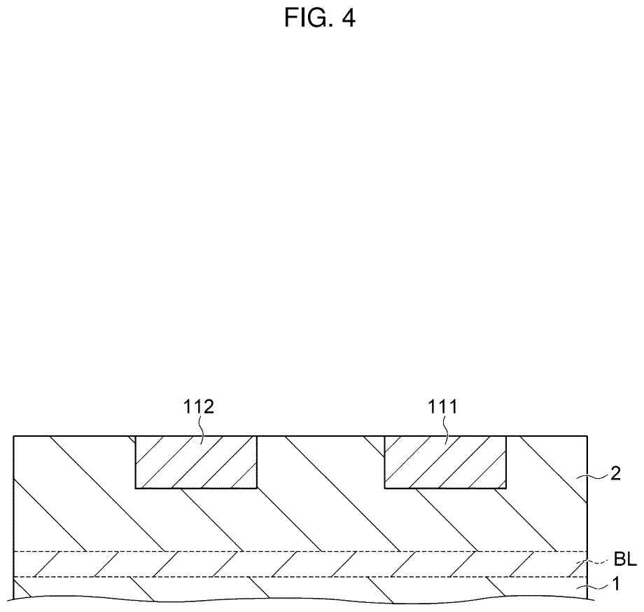

First, as illustrated in FIG. 4, impurity regions 111 and 112 of the second conductivity type are formed in a portion of the semiconductor layer 2 (Step 2). For example, in Step 2, using a mask (not shown) placed on the semiconductor layer 2, an impurity of the second conductivity type is introduced to a portion of the semiconductor layer 2. This way, the impurity region 111, which later becomes the impurity region 11, and the impurity region 112 are formed.

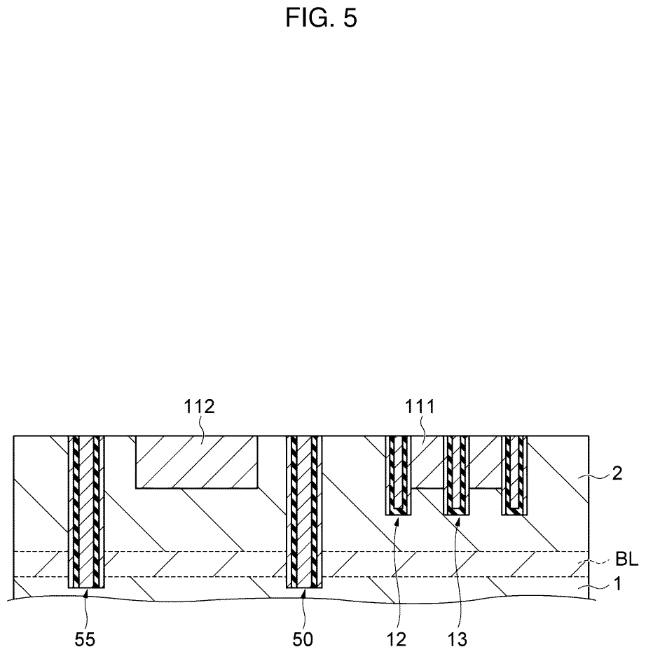

Next, as illustrated in FIG. 5, the trench structures 12 and 13 located in the semiconductor layer 2 and the trench structures 50 and 55 running through the semiconductor layer 2 are formed at the same time (Step 3). A portion of the impurity region 111 is removed when the trench structures 12 and 13 are formed, but the present disclosure is not limited thereto. The impurity region 111 does not have to be removed in the process of forming the trench structure 12. The trench structures 50 and 55 are each formed in positions that are separated from the impurity regions 111 and 112, respectively.

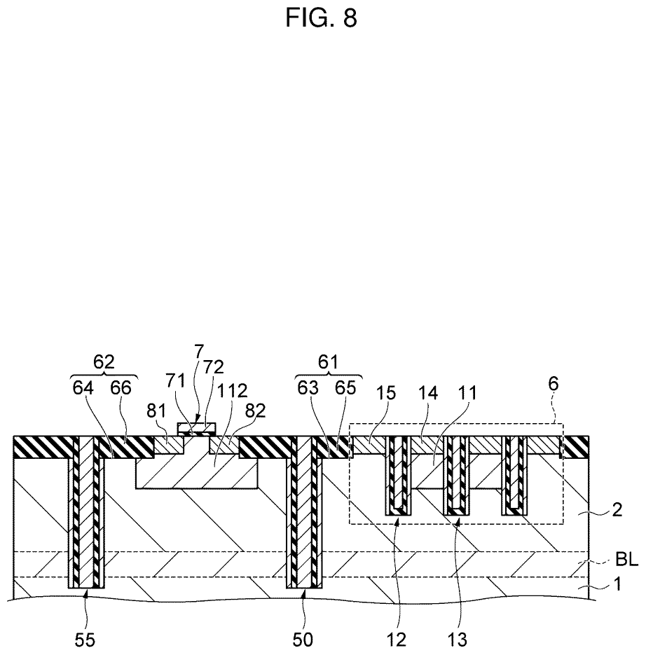

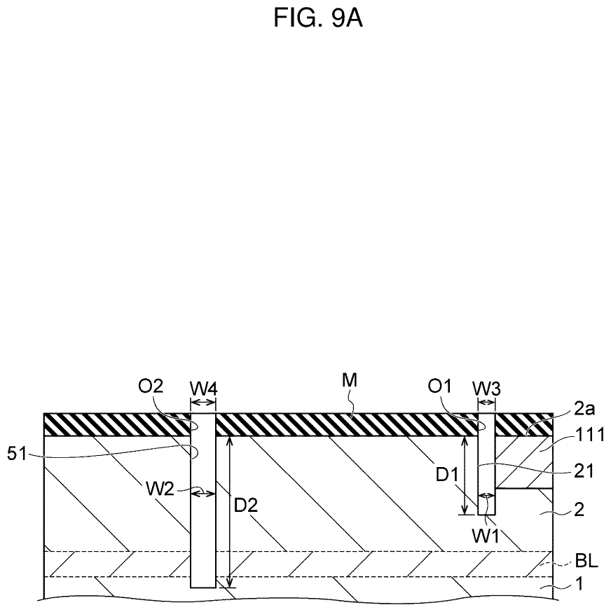

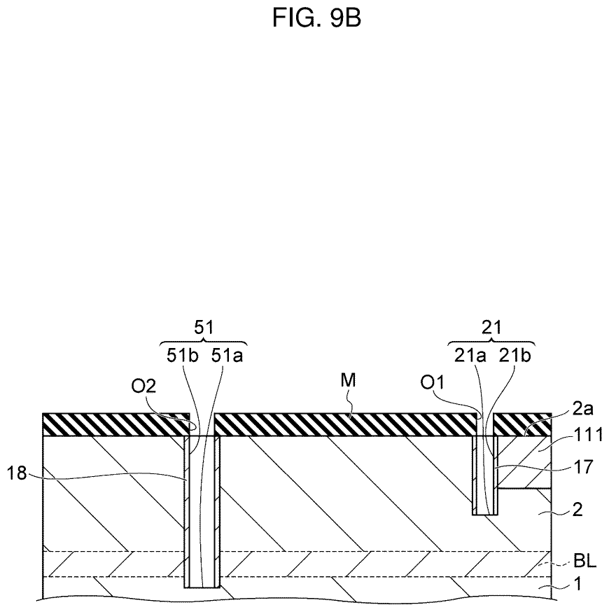

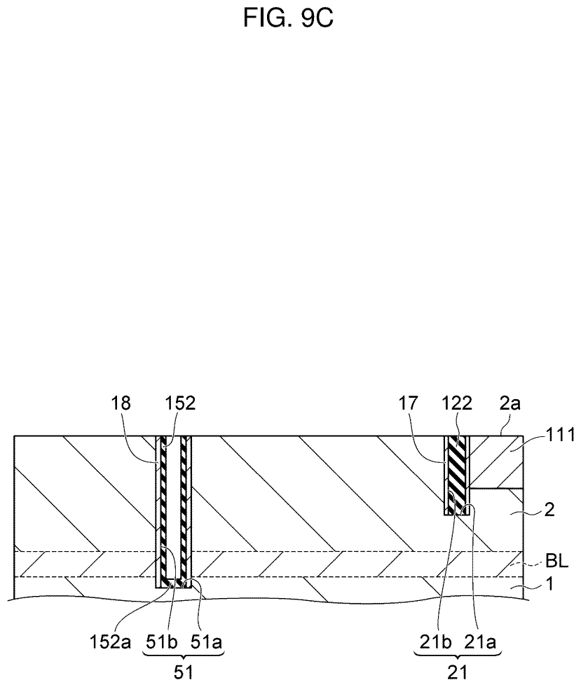

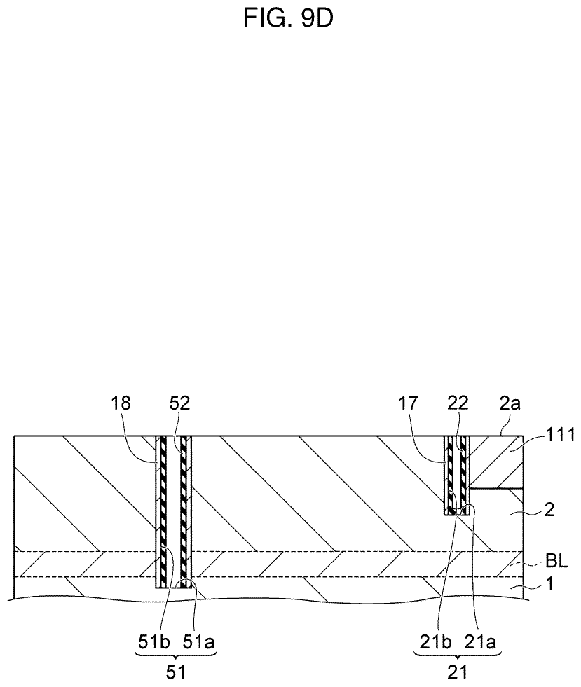

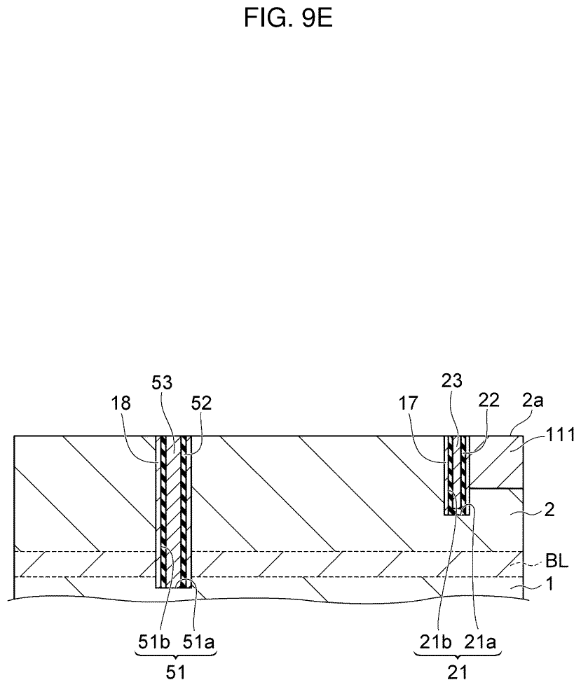

Below, Step 3 will be explained in detail with reference to FIGS. 9A to 9E. FIGS. 9A to 9E are each a schematic cross-sectional view for explaining one example of the manufacturing method of each trench structure. The manufacturing method of the trench structures 12 and 50 are explained with reference to FIGS. 9A to 9E, but the trench structures 13 and 55 are formed in the same manner. The trench structure 55 has similar characteristic and structure to those of the trench structure 50. The trench structure 55 functions as an element separation region for a horizontal MOSFET 7 described below (see FIG. 8 below), for example, and is formed separately from the trench structure 50. The trench structure 55 may be electrically connected to the trench structure 50, and may be integrally formed with the trench structure 50. The trench structure 55 and the trench structure 50 may have a common part.

First, as illustrated in FIG. 9A, the trench 21 having the semiconductor layer 2 as the bottom surface thereof, and the trench 51 that runs through the semiconductor layer 2 are formed simultaneously (Step 3A). In Step 3A, a hard mask M having openings O1, O2 is formed on the main surface 2a of the semiconductor layer 2. Next, in the semiconductor layer 2, etching is performed on the part exposed through the opening O1 and the part exposed through the opening O2 to form the trenches 21 and 51. The hard mask M is a component formed of a material having a low etching rate with respect to the etchant for the semiconductor layer 2 such as a silicon oxide film. The opening width W3 of the opening O1 is equal to the maximum value of the width W1 of the trench 21, and the opening width W4 of the opening O2 is equal to the maximum value of the width W2 of the trench 51. The hard mask M has a different shape from the mask used in Step 2.

In Step 3A, the trenches 21 and 51 are formed by anisotropic etching, such as the Bosch process using F radicals, for example. As a result, the width W1 of the trench 21 can be controlled to be equal to or smaller than the opening width W3, and the width W2 of the trench 51 can be controlled to be equal to or smaller than the opening width W4. The etching rate of the part of the semiconductor layer 2 exposed from the opening O1 becomes different from the etching rate of the part of the semiconductor layer 2 exposed from the opening O2 mainly due to the difference between the opening widths W3 and W4. Specifically, by making the opening widths W3 and W4 differ from each other, the etching rate of the part of the semiconductor layer 2 exposed from the opening O1 is made higher than the etching rate of the port exposed from the opening O2. This makes it possible to make the depth D1 of the trench 21 greater than the depth D2 of the trench 51 despite that the trenches 21 and 51 are formed at the same time. This way, in Step 3A, the trench 21 having the semiconductor layer 2 as the bottom surface thereof and the trench 51 having the semiconductor substrate 1 as the bottom surface thereof are formed.

Next, as shown in FIG. 9B, an impurity of the first conductivity type is introduced into the side surface 21b of the trench 21 and the side surface 51b of the trench 51 (Step 3B). As a result, the second impurity region 16 is formed along the side surface 21b, and the fourth impurity region 18 is formed along the side surface 51b. In Step 3B, impurities are simultaneously introduced into the side surfaces 21b and 51b by oblique ion implantation using the hard mask M, for example. In Step 3B, impurities are not introduced to the bottom surface 21a of the trench 21 or the bottom surface 51a of the trench 51, but the present disclosure is not limited thereto.

Next, as shown in FIG. 9C, an insulator 122 that fills up the trench 21 and an insulating layer 152 that covers the trench 51 are simultaneously formed (Step 3C). In Step 3C, the insulator 122 and the insulating layer 152 are simultaneously formed by a known method such as chemical vapor deposition (CVD), for example. In this embodiment, due to differences in width, depth and the like between the trenches 21 and 51, the trench 21 is completely filled with the insulator 122, whereas the trench 51 is not completely filled with the insulating layer 152. Therefore, a portion 152a of the insulating layer 152 located on the bottom surface 51a of the trench 51 is thinner than the other portion. Specifically, the thickness of the portion 152a is smaller than the depth of the insulator 122 (that is, the depth D1 of the trench 21). In Step 3C, the trench 21 does not have to be completely filled with the insulator 122. Although not shown in the figure, in Step 3C, the hard mask M can be used, but does not have to be used. If not used, the hard mask M is removed before Step 3C, for example. Removal of the hard mask M is performed by chemical-mechanical polishing (CMP), for example. The insulator can also be deposited on the main surface 2a of the semiconductor layer 2.

Next, as illustrated in FIG. 9D, a portion of the insulator 122 is removed in a way that the bottom surface 21a of the trench 21 is not exposed, and a portion 152a of the insulating layer 152 is removed in a way that the semiconductor substrate 1 is exposed in the trench 51 (Step 3D). In Step 3D, the insulator 122 and the insulating layer 152 are removed by anisotropic etching, for example. In Step 3D, the insulator 122 and the insulating layer 152 are etched to the extent that the portion 152a of the insulating layer 152 is removed. As described above, the thickness of the portion 152a is smaller than the depth of the insulator 122. This way, the insulator 22 covering the trench 21 and the insulating layer 52 covering the side surface 51b of the trench 51 are formed. In Step 3D, a part or all of the insulator deposited on the main surface 2a may be removed by etching. In Step 3D, a portion of the insulator remains on the main surface 2a, but the present disclosure is not limited thereto. The semiconductor substrate 1 and the semiconductor layer 2 can each function as the etching stopper in Step 3D.

Next, as illustrated in FIG. 9E, the conductor 23 separated from the semiconductor layer 2 is embedded in the trench 21, and the conductor 53 in contact with the semiconductor substrate 1 is embedded in the trench 51 (Step 3E). In Step 3E, first, a conductor (not shown) for filling the trenches 21 and 51 is formed by a known method such as sputtering or CVD. The conductor is formed not only in the trenches 21 and 51 but also on the main surface 2a of the semiconductor layer 2. Next, the portion of the conductor located on the main surface 2a of the semiconductor layer 2 is removed by a known method such as CMP. If an insulator, a hard mask M, or the like remains on the main surface 2a of the semiconductor layer 2, that insulator or the like may be removed at the same time as the portion of the conductor located on the main surface 2a of the semiconductor layer 2. By performing Steps 3A to 3E described above, the trench structures 12 and 50 are simultaneously formed as illustrated in FIG. 9E. Although not shown in the figure, the trench structures 13 and 55 are formed at the same time as the trench structures 12 and 50.

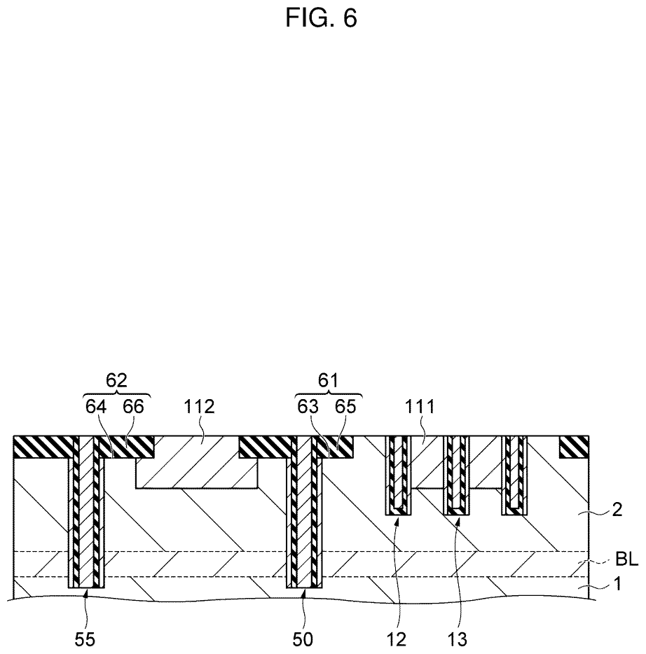

Next, returning to FIG. 6, STIs 61 and 62 are formed (Step 4). In Step 4, recesses 63 and 64 are formed in a portion of the semiconductor layer 2. The recess 63 has a ring shape that surrounds the impurity region 11 in a plan view, for example. The recess 63 is located outside the trench structure 12 and inside the trench structure 50 in a plan view. The recess 63 may be in contact with a part of the insulating layer 52 of the trench structure 50. The recess 64 has a ring shape that surrounds the impurity region 112 in a plan view, for example. The recess 64 may be in contact with another part of the insulating layer 52 of the trench structure 50. A portion of the impurity region 112 is removed when the recess 64 is formed, but the present disclosure is not limited thereto. Next, insulators 65 and 66 that fill the recesses 63 and 64 are formed respectively. In this way, the STI 61 including the recess 63 and the insulator 65, and the STI 62 including the recess 64 and the insulator 66 are formed.

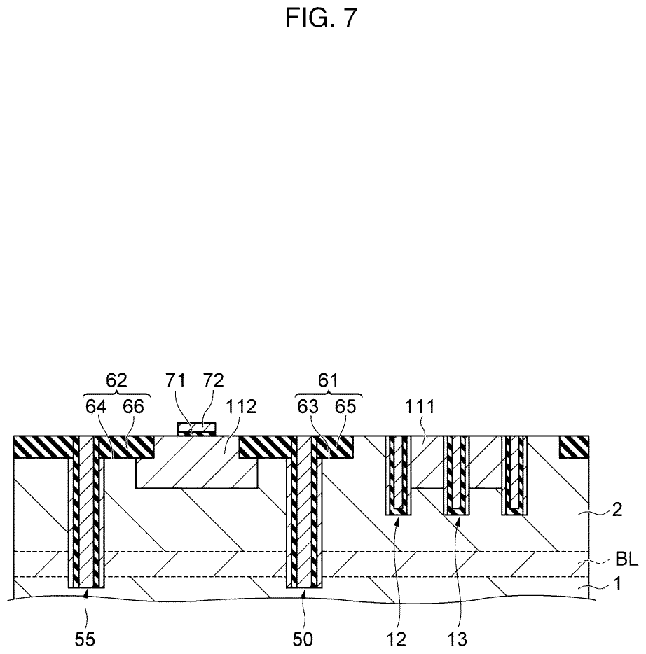

Next, as illustrated in FIG. 7, a gate insulating film 71 and a gate electrode 72 are formed on the impurity region 112 in this order (Step 5). In Step 5, the gate insulating film 71 and the gate electrode 72 are formed in this order by a known method. Examples of the gate insulating film 71 include an oxide insulating film. Examples of the gate electrode 72 include a metal such as aluminum (Al), copper (Cu), molybdenum (Mo), or tungsten (W), or polysilicon having the first or second conductivity type.

Next, as illustrated in FIG. 8, by introducing an impurity of the first conductivity type into the semiconductor layer 2 and the impurity regions 111 and 112, the first contact region 14 is formed in the impurity region 111, the second contact region 15 is formed in the semiconductor layer 2, and a third contact region 81 and a fourth contact region 82 are formed in the impurity region 112, respectively. The third contact region 81 is a high-concentration impurity region that functions as one of the source and drain, and the fourth contact region 82 is a high-concentration impurity region that functions as the other of the source and drain. Through Steps 1 to 6 described above, the vertical MOSFET 6 having the impurity regions 11, the trench structure 12, the first contact region 14, and the second contact region 15 is formed as the same time as the horizontal MOSFET 7 having the impurity region 112, the third contact region 81, the fourth contact region 82, the gate insulating film 71, and the gate electrode 72. The MOSFET 7 is an enhancement type FET, unlike the MOSFET 6.

In the semiconductor device 100 manufactured by the manufacturing method according to the embodiment described above, the trench structures 12 and 50 having differing depths are formed at the same time. Specifically, by making the width W1 of the trench 21 of the trench structure 12 differ from the width W2 of the trench 51 of the trench structure 50, the trench 21 having the semiconductor layer 2 as the bottom surface thereof and the trench 51 that runs through the semiconductor layer 2 can be formed simultaneously in Step 3A described above. Also, the insulator 22 of the trench structure 12 and the insulating layer 52 of the trench structure 50 can be formed simultaneously in Steps 3C and 3D described above, and the conductor 23 of the trench structure 12 and the conductor 53 of the trench structure 50 can be formed simultaneously in Step 3E described above. This makes it possible to form a plurality of types of trench structures 12 and 50 simultaneously without increasing the number of manufacturing steps for the semiconductor device 100. Therefore, by applying the manufacturing method of the semiconductor device 100 according to this embodiment, it is possible to efficiently manufacture a plurality of types of trench structures.

In this embodiment, by simultaneously forming a plurality of types of trench structures (i.e., trench structures 12 and 50), it is possible to simultaneously form the trench structure 50, which is a DTI, and the gate of the vertical MOSFET 6. Therefore, in this embodiment, the process of forming a trench structure only for a vertical MOSFET is not necessary. That is, a mask for forming a trench structure only for a vertical depression type MOSFET can be omitted. This makes it possible to effectively reduce the manufacturing cost of the semiconductor device 100 including the MOSFET 6 and the trench structure 50 (DTI).

Furthermore, in this embodiment, the vertical MOSFET 6 and the horizontal MOSFET 7 can be formed at the same time. This way, it is possible to efficiently manufacture the semiconductor device 100 including a plurality of type of FETs.

In one example, the ratio of the width W1 of the trench 21 to the depth D1 of the trench 21 is 22% or greater and less than or equal to 2667% of the ratio of the width W2 of the trench 51 to the depth D2 of the trench 51, for example. In this case, when the trench 51 that runs through the semiconductor layer 2 is formed, the bottom surface 21a of the trench 21 can be easily defined by the semiconductor layer 2.

In one example, the manufacturing method includes Step 3B of introducing an impurity of the first conductivity type into the side surface 21b of the trench 21 and the side surface 51b of the trench 51 before the insulator 22 and the insulating layer 52 are formed. In this case, the second impurity region 16 that functions as the depression part can be formed simultaneously with the formation of the fourth impurity region 18 included in the trench structure 50, and therefore, the manufacturing process can be effectively simplified.

In one example, the manufacturing method includes, prior to the formation of the trenches 21 and 51, Step 2 of forming the impurity regions 111 and 112 of the second conductivity type in the semiconductor layer 2, and Step 5 of forming one of the source and drain in the semiconductor layer 2 and forming the other of the source and drain in the impurity region 111 by introducing an impurity of the first conductivity type into the semiconductor layer 2 and the impurity regions 111 and 112, and the source and drain are in contact with the side surface 21b that is the surface of the trench 21. In this case, it is possible to effectively form the MOSFETs 6 and 7.

In one example, the bottom surface 21a of the trench 21 is located closer to the semiconductor substrate 1 than the impurity region 11 in the z-axis direction. In this case, it is possible to effectively achieve the ON-OFF characteristics of the MOSFET 6.

In one example, the trench 21 is surrounded by the trench 51 when viewed from the z-axis direction. In this case, a leak current from the MOSFET 6 to the outside and a leak current from the outside to the MOSFET 6 can be reduced.

In one example, each of the conductors 23 and 53 is polysilicon. In this case, it is possible to embed the conductors 23 and 53 respectively in the trenches 21 and 51 easily.

In one example, the trench structure 12 including the trench 21 surrounds the impurity region 11 and the first contact region 14 in a plan view, and the second contact region 15 surrounds the trench structure 12 including the trench 21 in a plan view. In this case, it is possible to effectively increase the current path of the MOSFET 6.

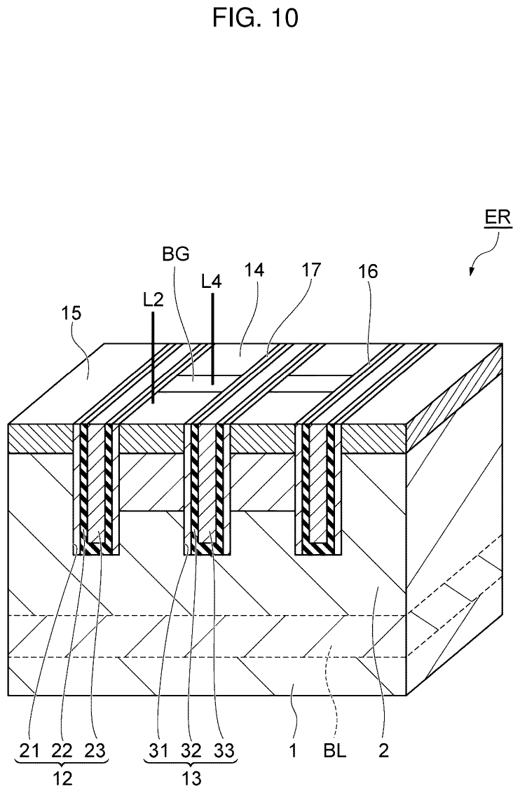

Below, key parts of a semiconductor device of a modification example will be explained with reference to FIG. 10. Below, descriptions that overlap with the embodiment described above will be omitted. FIG. 10 is a cross-sectional perspective view showing a main part of a semiconductor device according to a modification example. As illustrated in FIG. 10, in this modification example, a back-gate region BG is also formed in the impurity region 11, in addition to the first contact region 14. The back-gate region BG, which is an impurity region that functions as the back gate of the MOSFET, is of the second conductivity type and electrically connected to wiring L4. The back-gate region BG extends from the second impurity region 16 to the third impurity region 17, but the present disclosure is not limited thereto. The impurity concentration of the back-gate region BG is greater than the impurity concentration of the impurity region 11, and is 1.0×10¹⁸ cm⁻³ or greater and less than or equal to 1.0×10²¹ cm⁻³, for example. With the modification example described above, it is possible to achieve actions and effects similar to the embodiment described above.

An embodiment of one aspect of the present disclosure and a modification example have been described, but the present disclosure may be embodied in other forms.

In this embodiment, the semiconductor device can be applied to a power module used for an inverter circuit that drives electric motors used as power sources for automobiles (including electric vehicles), trains, industrial robots, air conditioners, air compressors, electric fans, vacuum cleaners, dryers, refrigerators and the like, for example. The semiconductor device can be applied to a power module used for an inverter circuit of a power generator such as a solar panel and wind power generator. Alternatively, the semiconductor device can be applied to a circuit module that constitutes an analog control power supply, a digital control power supply, or the like.

Although an embodiment of one aspect of the present disclosure and modification examples have been described in detail above, these are merely specific examples used to clarify the technical content of the present disclosure, and the present disclosure should not be interpreted as being limited to these specific examples, and the scope of the present disclosure is limited only by the appended claims As described above, various embodiments in this disclosure may be specified as follows.

Below, representative examples extracted from the present specification and descriptions of the drawings will be explained.

[A1] A manufacturing method of a semiconductor device, including:
forming a semiconductor layer of a first conductivity type located on a substrate;
forming a first trench having the semiconductor layer as a bottom surface thereof at the same time as a second trench that runs through the semiconductor layer;
forming an insulator that fills up the first trench at the same time as an insulating layer that covers the second trench,
removing a part of the insulator in such a manner that the bottom surface of the first trench is not exposed, and removing a part of the insulating layer in such a manner that the semiconductor substrate is exposed in the second trench; and
embedding in the first trench a first conductor separated from the semiconductor layer, and embedding in the second trench a second conductor that is in contact with the semiconductor substrate,
wherein a width of the second trench is greater than a width of the first trench.

[A2] The manufacturing method of a semiconductor device according to [A1], wherein the width of the second trench is 104% or greater and less than or equal to 900% of the width of the first trench.

[A3] The semiconductor device according to [A1] or [A2], wherein a ratio of the width of the first trench to a depth of the first trench is 3.7% or greater and less than or equal to 450% of a ration of the width of the second trench to a depth of the second trench.

[A4] The semiconductor device according to any one of [A1] to [A4], further including introducing an impurity of a first conductivity type into a side surface of the first trench and a side surface of the second trench before forming the insulator and the insulating layer.

[A5] The manufacturing method of a semiconductor device according to [A1] to [A4], further including forming an impurity region of a second conductivity type that differs from the first conductivity type in the semiconductor layer before forming the first trench and the second trench; and
forming one of a source and drain in the semiconductor layer and forming the other of a source and drain in the impurity region by introducing an impurity of the first conductivity type into the semiconductor layer and the impurity region, wherein the source and the drain are both in contact with a surface of the first trench.

[A6] The manufacturing method of a semiconductor device according to [A5], wherein the bottom surface of the first trench is located closer to the semiconductor substrate than the impurity region in a thickness direction of the semiconductor layer.

[A7] The manufacturing method of a semiconductor device according to [A5] or [A6], wherein the first conductor functions as a gate.

[A8] The manufacturing method of a semiconductor device according to any one of [A1] to [A7], wherein the first trench is surrounded by the second trench when viewed from a thickness direction of the semiconductor layer.

[A9] The manufacturing method of a semiconductor device according to any one of [A1] to [A8], wherein the first conductor and the second conductor are each polysilicon. [A10] A semiconductor device, including:
a semiconductor layer of a first conductivity type that is located on a semiconductor substrate;
an impurity region of a second conductivity type that differs from the first conductivity type, the impurity region being located in the semiconductor layer;
a first trench having the semiconductor layer as a bottom surface thereof and adjacent to the impurity region;
a first conductor located in the first trench and separated from the semiconductor layer;
a first contact region of the first conductivity type that is located on the impurity region in the semiconductor layer and that is in contact with a side surface of the first trench;
a second contact region of the first conductivity type that is located in the semiconductor layer and that is in contact with the side surface of the first trench;
a second trench that runs through the semiconductor layer and surrounds the first trench; and
a second conductor located in the second trench and in contact with the semiconductor substrate,
wherein a width of the second trench is greater than a width of the first trench.

[A11] The semiconductor device according to [A10], wherein the width of the second trench is 104% or greater and less than or equal to 900% of the width of the first trench.

[A12] The semiconductor device according to [A10] or [A11], wherein a ratio of the width of the first trench to a depth of the first trench is 3.7% or greater and less than or equal to 450% of a ration of the width of the second trench to a depth of the second trench.

[A13] The semiconductor device according to any one of [A10] to [A12], wherein the first conductor functions as a gate.

[A14] The semiconductor device according to any one of [A10] to [A13], wherein the first conductor and the second conductor are each polysilicon.

[A15] The semiconductor device according to any one of [A10] to [A14], wherein the side surface of the first trench is defined by a second impurity region of the first conductivity type located in the semiconductor layer.

[A16] The semiconductor device according to any one of [A10] to [A15], wherein the first trench surrounds the impurity region and the first contact region in a plan view, and the second contact region surrounds the first trench in a plan view.

What is claimed is:

1. A manufacturing method of a semiconductor device, comprising:
forming a semiconductor layer of a first conductivity type located on a substrate;
forming a first trench having the semiconductor layer as a bottom surface at a same time as forming a second trench that runs through the semiconductor layer;
forming an insulator that fills up the first trench at a same time as forming an insulating layer that covers the second trench,
removing a part of the insulator in such a manner that the bottom surface of the first trench is not exposed, and removing a part of the insulating layer in such a manner that the semiconductor substrate is exposed in the second trench; and
embedding in the first trench a first conductor separated from the semiconductor layer, and embedding in the second trench a second conductor that is in contact with the semiconductor substrate,
wherein a width of the second trench is greater than a width of the first trench.

2. The manufacturing method of a semiconductor device according to claim 1, wherein the width of the second trench is 104% or greater and less than or equal to 900% of the width of the first trench.

3. The manufacturing method of a semiconductor device according to claim 1, wherein a ratio of the width of the first trench to a depth of the first trench is 3.7% or greater and less than or equal to 450% of a ratio of the width of the second trench to a depth of the second trench.

4. The manufacturing method of a semiconductor device according to claim 1, further comprising introducing an impurity of a first conductivity type into a side surface of the first trench and a side surface of the second trench before forming the insulator and the insulating layer.

5. The manufacturing method of a semiconductor device according to claim 1, further comprising:
forming an impurity region of a second conductivity type that differs from the first conductivity type in the semiconductor layer before forming the first trench and the second trench; and
forming one of a source and a drain in the semiconductor layer and forming another of the source and the drain in the impurity region by introducing an impurity of the first conductivity type to the semiconductor layer and the impurity region,
wherein the source and the drain are both in contact with a surface of the first trench.

6. The manufacturing method of a semiconductor device according to claim 5, wherein the bottom surface of the first trench is located closer to the semiconductor substrate than is the impurity region in a thickness direction of the semiconductor layer.

7. The manufacturing method of a semiconductor device according to claim 5, wherein the first conductor functions as a gate.

8. The manufacturing method of a semiconductor device according to claim 1, wherein the first trench is surrounded by the second trench when viewed from a thickness direction of the semiconductor layer.

9. The manufacturing method of a semiconductor device according to claim 1, wherein the first conductor and the second conductor are each polysilicon.

10. A semiconductor device, comprising:
a semiconductor layer of a first conductivity type located on a semiconductor substrate;
an impurity region of a second conductivity type that differs from the first conductivity type, the impurity region being located in the semiconductor layer;
a first trench having the semiconductor layer as a bottom surface thereof and adjacent to the impurity region;
a first conductor located in the first trench and separated from the semiconductor layer;
a first contact region of the first conductivity type located on the impurity region in the semiconductor layer and in contact with a side surface of the first trench;
a second contact region of the first conductivity type located in the semiconductor layer and in contact with the side surface of the first trench;
a second trench that runs through the semiconductor layer and surrounds the first trench; and
a second conductor located in the second trench and in contact with the semiconductor substrate,
wherein a width of the second trench is greater than a width of the first trench.

11. The semiconductor device according to claim 10, wherein the width of the second trench is 104% or greater and less than or equal to 900% of the width of the first trench.

12. The semiconductor device according to claim 10, wherein a ratio of the width of the first trench to a depth of the first trench is 3.7% or greater and less than or equal to 450% of a ratio of the width of the second trench to a depth of the second trench.

13. The semiconductor device according to claim 10, wherein the first conductor functions as a gate.

14. The semiconductor device according to claim 10, wherein the first conductor and the second conductor are each polysilicon.

15. The semiconductor device according to claim 10, wherein the side surface of the first trench is defined by a second impurity region of the first conductivity type located in the semiconductor layer.

16. The semiconductor device according to claim 10, wherein the first trench surrounds the impurity region and the first contact region in a plan view, and the second contact region surrounds the first trench in a plan view.
